(19) United States
(12) Patent Application Publication
(10) Pub. No.: US 2025/0232823 A1
(43) Pub. Date: Jul. 17, 2025

(54) HIDDEN MAJORITY VOTE PROGRAM VERIFY SCHEME FOR A MEMORY DEVICE

(71) Applicant: Micro Technology, Inc., Boise, ID (US)

(72) Inventors: Yu-Chung LIEN, San Jose, CA (US); Ching-Huang LU, Fremont, CA (US); Zhenming ZHOU, San Jose, CA (US)

(21) Appl. No.: 18/982,873

(22) Filed: Dec. 16, 2024

Related U.S. Application Data
(60) Provisional application No. 63/621,513, filed on Jan. 16, 2024.

(51) Int. Cl. G11C 16/34; G11C 13/00; G11C 16/04; G11C 16/10

(52) U.S. Cl. CPC G11C 16/3459; G11C 13/0064; G11C 13/0069; G11C 16/0483; G11C 16/10; G11C 13/0004

(57) ABSTRACT

In some implementations, a memory device may program host data to memory using a program scheme, including by permitting, during a first programming pulse, a memory cell to receive a first program voltage; and by inhibiting, during a second and third programming pulse, the memory cell from receiving a second and third program voltage, respectively. The memory device may verify the program scheme using a majority vote program verify scheme, including by performing a first, second, and third program verify procedure for the memory cell following the first, second, and third programming pulse, respectively; and by determining whether the memory cell passes a majority of the first, second, and third program verify procedures. The memory device may inhibit or permit the memory cell to receive a fourth program voltage based on whether the memory cell passes the majority of the first, second, and third program verify procedures.

### CROSS-REFERENCE TO RELATED APPLICATION

This Patent Application claims priority to U.S. Provisional Patent Application No. 63/621,513, filed on Jan. 16, 2024, entitled “HIDDEN MAJORITY VOTE PROGRAM VERIFY SCHEME FOR A MEMORY DEVICE,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to a hidden majority vote program verify scheme for a memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of performing a hidden majority vote program verify scheme for a memory device.

FIG. 2 is a diagram of example components included in a memory device.

FIG. 3 is a diagram of an example associated with a program verify step of a cell in a memory device.

FIG. 4 is a diagram of an example of a hidden majority vote program verify scheme for a memory device.

FIG. 5 is a flowchart of an example method associated with a hidden majority vote program verify scheme for a memory device.

### DETAILED DESCRIPTION

A memory controller may write data (e.g., host data) to a memory using a programming scheme. In some examples, a programming scheme may include trapping a voltage (e.g., a threshold voltage (Vₜₕ)) in a memory cell, with the level of trapped voltage corresponding to a data state that the cell is intended to store. To ensure that a memory cell includes an appropriate threshold voltage to indicate a desired data state, the memory controller may perform a program verify procedure in which a level of trapped voltage in the cell is sensed shortly after the cell receives a programming pulse. If the trapped voltage in the cell exceeds a certain threshold, the cell may be deemed to pass the program verify procedure, and thus the memory controller may inhibit the cell from receiving any additional programming pulses in order to ensure the cell is not over-programmed. However, if the trapped voltage in the cell does not exceed the certain threshold, the cell may be deemed to fail the program verify procedure, and thus the memory controller may permit the cell to receive one or more additional programming pulses in order to raise the voltage level in the cell. In some examples, a random telegraph noise (RTN) and/or other phenomena may cause inaccurate readings during a program verify procedure. This may result in corrupted data, unreliable memory systems, and high resource consumption associated with identifying and correcting program errors.

In some examples, in order to reduce instances of false readings due to RTN or other phenomena, a memory controller may verify a programming operation multiple times. For example, the memory controller may implement a majority vote program verify scheme, in which a trapped voltage is read three or more times, with the cell being deemed to have passed or failed based on whether a majority of the sensed voltages satisfy a certain threshold. For example, if at least two out of the three sensed voltages pass (e.g., exceed the certain threshold), the cell may be deemed to pass the majority vote program verify scheme and thus the cell may be inhibited from receiving any subsequent programming pulses. However, if at least two out of the three sensed voltages fail (e.g., do not pass exceed the certain threshold), the cell may be deemed to fail the majority vote program verify scheme and thus the cell may be permitted to receive subsequent programming pulses in order to increase the threshold voltage within the cell. Implementing a majority vote program verify scheme may adversely affect a performance of a memory device, because a programming time associated with the memory device may need to be increased to accommodate the multiple program verify operations and/or multiple additional sensing circuits may need to be implemented in the memory device to perform the multiple program verify operations in parallel. Accordingly, although implementing a majority vote program verify scheme may result in increased reliability of memory devices, this may come at an expense of slow programming procedures and/or high circuitry overhead required to perform the multiple sensing operations.

Some implementations described herein enable a “hidden” majority vote program verify scheme that may be performed without a program time penalty and/or without requiring multiple sensing circuits to operate in parallel. In some implementations, the hidden majority vote program verify scheme may include performing, following each of multiple (e.g., three) programming pulses for a memory cell, a corresponding program verify procedure (e.g., a procedure associated with sensing whether the cell satisfies a certain threshold), and determining whether the memory cell passes a majority of the program verify procedures (e.g., determining whether the memory cell satisfies the threshold for at least two out of three program verify procedures). In implementations in which the memory cell passes a majority of the program verify procedures, the memory cell may be inhibited from subsequent programming pulses in order to ensure the cell is not over-programmed. However, in implementations in which the memory cell does not pass a majority of the program verify procedures, the memory cell may be permitted to receive one or more subsequent programming pulses, thereby increasing the trapped voltage in the memory cell and thus programming the memory cell to a threshold voltage corresponding to a data value that the cell is intended to store. In this way, a reliability and/or a read/write bandwidth (RWB) gain of a memory device may be improved as compared to memory devices employing only a single program verify procedure, while overall programming time associated with a programming procedure, circuitry overhead associated with a program verify procedure, and/or resource consumption associated with identifying and correcting programming errors may be reduced as compared to programming schemes employing traditional program verify procedures.

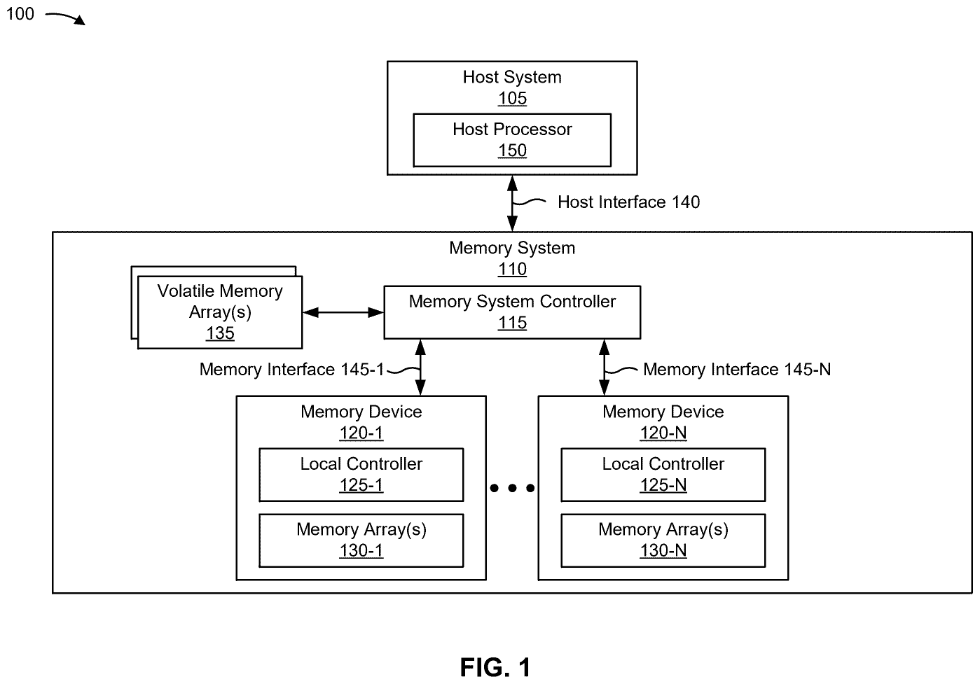

FIG. 1 is a diagram illustrating an example system 100 capable of performing a hidden majority vote program verify scheme for a memory device. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N(where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N(where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to receive a program command instructing a memory device to write host data to a memory; program the host data to the memory using a program scheme associated with multiple programming pulses, including by permitting, during a first programming pulse, of the multiple programming pulses, a memory cell to receive a first program voltage; inhibiting, during a second programming pulse, of the multiple programming pulses, the memory cell from receiving a second program voltage; and inhibiting, during a third programming pulse, of the multiple programming pulses, the memory cell from receiving a third program voltage; verify the program scheme using a majority vote program verify scheme, including by performing, following the first programming pulse, a first program verify procedure for the memory cell; performing, following the second programming pulse, a second program verify procedure for the memory cell; performing, following the third programming pulse, a third program verify procedure for the memory cell; and determining whether the memory cell passes a majority of the first program verify procedure, the second program verify procedure, and the third program verify procedure; and perform one of: inhibiting, during a fourth programming pulse, of the multiple programming pulses, the memory cell from receiving a fourth program voltage when the memory cell passes the majority of the first program verify procedure, the second program verify procedure, and the third program verify procedure, or permitting, during the fourth programming pulse, the memory cell to receive the fourth program voltage when the memory cell does not pass the majority of the first program verify procedure, the second program verify procedure, and the third program verify procedure.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

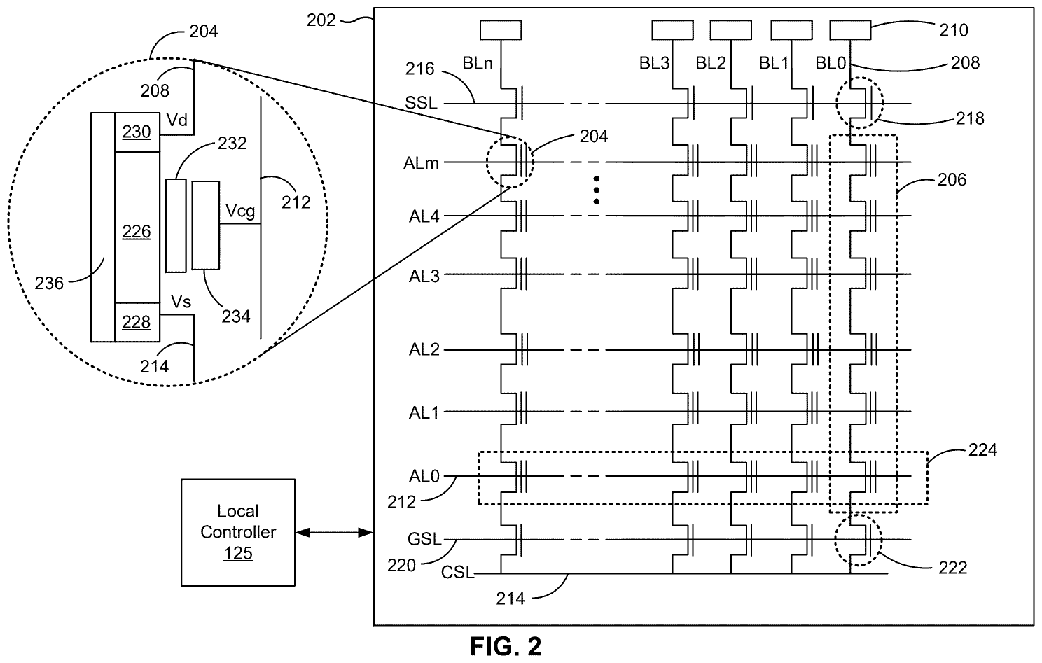

FIG. 2 is a diagram of example components included in a memory device 120. As described above in connection with FIG. 1, the memory device 120 may include a local controller 125 and memory arrays 130. For example, the memory device shown in FIG. 2 includes a memory array 202, which may correspond to the memory array 130 described above in connection with FIG. 1.

In FIG. 2, the memory array 202 is a NAND memory array. However, in some implementations, the memory array 202 may be another type of memory array, such as a NOR memory array, a resistive RAM (RRAM) memory array, a magnetoresistive RAM (MRAM) memory array, a ferroelectric RAM (FeRAM) memory array, a spin-transfer torque RAM (STT-RAM) memory array, a phase-change memory (PCM) array, or the like. In some implementations, the memory array 202 is part of a three-dimensional stack of memory arrays, such as 3D NAND flash memory, 3D NOR flash memory, or the like.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 (sometimes called a string) may include multiple memory cells 204 connected in series. A NAND string 206 is coupled to a bit line (BL) 208 (sometimes called a digit line or a column line, and shown as BL0-BLn). Data can be read from or written to the memory cells 204 of a NAND string 206 via a corresponding bit line 208 using one or more input/output (I/O) components 210 (e.g., an I/O circuit, an I/O bus, a page buffer, and/or a sensing component, such as a sense amplifier). Memory cells 204 of different NAND strings 206 (e.g., one memory cell 204 per NAND string 206) may be coupled with one another via access lines 212 (sometimes called word lines (WLs) or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation).

In some implementations, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). The memory device 120 may store a data state in the memory cell 204 by charging the floating gate 232 to a particular voltage associated with the data state and/or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Vcg may be supplied from an access line 212, and a source voltage Vs may be supplied via the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states so that all of the other memory cells 204 in the NAND string 206 conduct, and the I/O component 210 can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block and/or a subset of memory cells of the block.

In some examples, a memory device (e.g., memory device 120 and/or a similar memory device) may verify a programmed state of a memory cell during a program operation. For example, during a programming phase of a given memory cell, data may be written to the memory cell, such as by injecting a charge into a floating gate of a transistor thereby changing the cell's threshold voltage to a voltage corresponding to a data state that the cell is intended to store, as described above. During a program verify phase and/or during a program verify procedure for the memory cell (sometimes referred to herein as a program verify operation, a program verify step, and/or a program verify scheme), a memory controller (e.g., memory system controller 115, local controller 125, and/or a similar controller) may read back the data just written to the cell to ensure that the correct threshold voltage has been achieved and/or that the correct data value has been stored. In examples in which the correct threshold voltage has not been achieved, the memory controller may perform additional programming steps, such as by permitting one or more additional programming pulses to be applied to the cell in order to further inject change into the cell's floating gate.

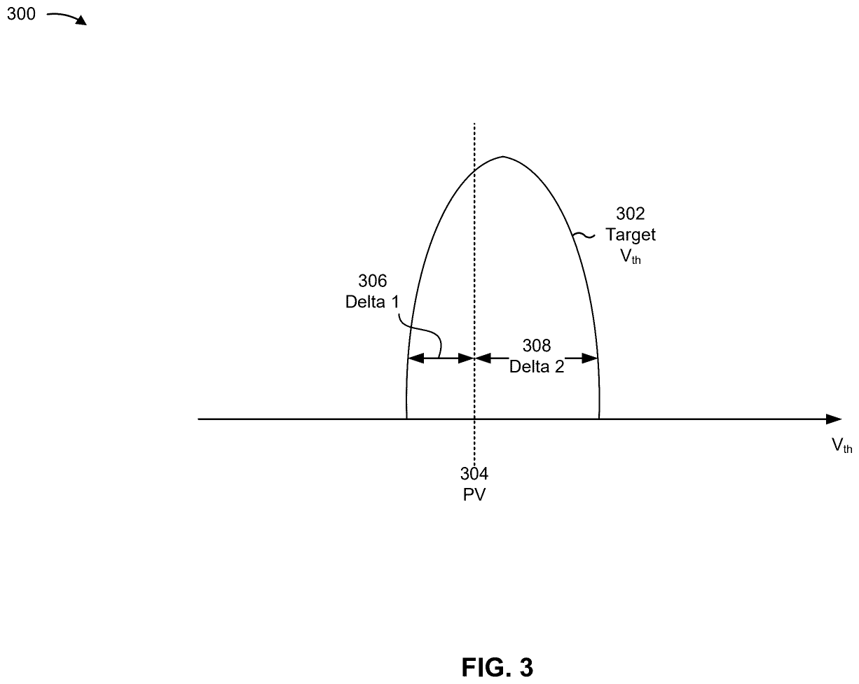

In some examples, a memory cell may pass a program verify step, notwithstanding that the cell has not been programmed to the appropriate threshold voltage. For example, in some examples noise (e.g., RTN) or other interference may affect a program verify procedure in such a way that the memory controller determines that the memory cell passes a program verify step, even though the threshold voltage is not at an appropriate level and/or does not correspond to a data value that the cell is intended to store. This may be more readily understood with reference to FIG. 3.

As indicated above, FIG. 2 is provided as an example. Other examples may differ from what is described with regard to FIG. 2.

FIG. 3 is a diagram of an example 300 associated with a program verify step of a cell in a memory device. The example 300 may be associated with a memory device, such as the memory device 120 and/or another device associated with memory system 110.

Reference number 302 shows a target distribution for threshold voltages (e.g., Vₜₕ) in a certain type of cell following a programming step. In some examples, a program verify step may be used to determine whether a trapped voltage in a given cell is near a center of the target distribution. In cases in which a trapped voltage is near the center of the target distribution, a memory cell may be deemed to pass the program verify step, and the cell may be inhibited from further programming pulses so that the cell does not become over-programmed. However, in cases in which a trapped voltage in a given cell is not near the center of the target distribution, the cell may be deemed to fail the program verify step, and the cell may be subject to further programming pulses, such as for a purpose of increasing the threshold voltage in the cell.

In some examples, a trapped voltage may not be near the center of the target voltage distribution indicated by reference number 302, but a memory cell may nonetheless be deemed to pass the program verify step due to noise or other phenomena causing an error in the reading of the trapped voltage. For example, RTN may cause an error in a reading of the trapped voltage, resulting in an otherwise improperly programmed memory cell to pass a program verify step. RTN may refer to a phenomenon observed in memory devices that is characterized by random and discrete switching between two or more conduction levels in a device. In some examples, RTN may be caused by trapping and detrapping of charge carriers (e.g., electrons) at defect sites within a semiconductor material. RTN may be more severe for memory cells associated with a high resistance state (HRS) (e.g., low current) as compared to memory cells associated with a low resistance state (LRS) (e.g., high current). In some examples, RTN may cause the threshold voltage of a cell to fluctuate unpredictably, resulting in read current fluctuations during a program verify step and/or read errors during a program verify step.

For example, as indicated by reference number 302, a memory cell may be programmed to a certain voltage within the threshold voltage distribution curve in order to store a certain data value. In some examples, in order to determine whether a given threshold voltage falls within the threshold voltage distribution curve, the trapped voltage of a cell may be sensed during a program verify procedure. For example, as indicated by reference number 304, during the program verify procedure a sensing circuit of a memory controller or a similar component may determine whether a trapped voltage within a cell satisfies at least a program verify (PV) voltage. In some examples, the PV voltage may be below a center of the target threshold distribution, such that if the sensed voltage satisfies the PV voltage, the cell is considered to store a trapped voltage near to a center of the threshold voltage distribution curve as thus is deemed to pass the program verify procedure. In such cases, the cell may be inhibited from receiving any subsequent programming pulses. However, if the sensed voltage does not satisfy the PV voltage, the cell is considered to store a trapped voltage that falls below the center of the threshold voltage distribution curve, as thus is deemed to fail the program verify procedure. In such cases, the cell may be permitted to be further programmed during subsequent programming pulses in order to raise the trapped voltage to near a center of the threshold voltage distribution curve.

In some examples, a cell may be deemed to pass a program verify procedure even though the trapped voltage falls below the PV voltage indicated by reference number 304. For example, RTN or similar phenomena may affect the reading of the trapped voltage during the program verify step, resulting in a sensing circuit to determine that a cell passes the program verify procedure (e.g., to determine that cell stores a trapped voltage near the center of the threshold voltage distribution curve) even though the trapped voltage falls below the PV voltage. In such examples, the cell may be inhibited from additional programming pulses, degrading an odd edge margin associated with the cell. More particularly, the threshold voltage distribution curve may be characterized by a delta 1 portion, indicated by reference number 306 in FIG. 3, which may correspond to an area of the threshold voltage distribution curve that is associated with voltages less than the PV voltage (and thus voltages that should be deemed to fail the program verify step). Similarly, the threshold voltage distribution curve may be characterized by a delta 2 portion, indicated by reference number 308 in FIG. 3, which may correspond to an area of the threshold voltage distribution curve that is associated with voltages more than the PV voltage (and thus voltages that should be deemed to pass the program verify step). Due to the effects of RTN during the program verify step or otherwise, a cell storing a trapped voltage within the delta 1 region may incorrectly be deemed to pass the program verify procedure and/or a cell storing a trapped voltage with the delta 2 region may incorrectly be deemed to fail the program verify procedure. This may negatively impact a RWB associated with the cell, resulting in read/write errors, degraded memory device performance, and/or high power, computing, and storage resource consumption associated with correcting read/write errors.

In some examples, program verify errors caused by RTN or the like may become more pronounced with increased bits-per-cell (BPC) and/or reduced oxide-nitride-oxide (ON) pitches used in memory devices. For example, quad-level cells (QLCs) and/or higher BPC memory devices may be associated with very small step sizes, with each level going through numerous loops during a program operation (e.g., during a second, or fine, pass of a program operation). Accordingly, a quantity of misjudged cells during program verify operations of the numerous loops may accumulate and thus cause an observable impact in a memory device. Moreover, an effect of RTN may become more severe with ON pitch scaling, resulting in an aggregation of reliability loss due to RTN for devices employing relatively small ON pitches.

In some examples, a programming operation may be verified multiple times, such as for a purpose of reducing an impact to a RWB of a memory cell caused by RTN. For example, a majority vote program verify scheme may be used to verify a programming operation, in which a trapped voltage in a cell is sensed three or more times by a sensing circuit, with the cell being deemed to have passed or failed based on whether a majority of the sensed voltages satisfy the PV voltage. For example, if at least two out of the three sensed voltages pass (e.g., exceed the PV voltage), the cell may be deemed to pass the majority vote program verify scheme and thus the cell may be inhibited from receiving any subsequent programming pulses. However, if at least two out of the three sensed voltages fail (e.g., do not pass exceed the PV voltage), the cell may be deemed to fail the majority vote program verify scheme and thus the cell may be permitted to receive subsequent programming pulses in order to increase the threshold voltage within the cell.

Implementing such a majority vote program verify scheme may adversely affect a performance of a memory device, because a programming time associated with the memory device may be increased to accommodate the multiple program verify operations and/or multiple additional sensing circuits may need to be implemented in the memory device. For example, to achieve a majority vote program scheme in which a trapped voltage in a cell is sensed three times, a memory device may employ three sets of sensing circuits for each BL that are capable of performing sensing concurrently. In such examples, a majority vote program scheme may result in no additional sensing time as compared to program verify schemes employing only one sensing circuit, but nonetheless may result in a circuit area penalty at the memory device as three sensing circuits (instead of one) may be needed to perform the program verify procedure. On the other hand, a memory device may employ one set of sensing circuits for each BL to perform that senses a trapped voltage three times consecutively. Such examples may result in additional time to complete a program verify procedure because as capacitor or similar component used in the sensing circuit may need to be charged and/or boosted three times, once during each program verify procedure.

Some implementations described herein enable a majority vote program verify scheme that may be performed without a program time penalty and/or without requiring multiple sensing circuits to operate in parallel. In that regard, the majority vote program verify operation according to some of the implementations described herein may be referred to as a “hidden” majority vote program verify scheme. In some implementations, the hidden majority vote program verify scheme may include performing, following each of multiple (e.g., three) programming pulses for a memory cell, a corresponding program verify procedure (e.g., a procedure associated with sensing whether the cell satisfies a PV voltage threshold), and determining whether the memory cell passes a majority of the program verify procedures (e.g., determining whether the memory cell meets the PV voltage threshold for at least two out of three program verify procedures). In implementations in which the memory cell passes a majority of the program verify procedures, the memory cell may be inhibited from subsequent programming pulses in order to not over-program the cell. However, in implementations in which the memory cell does not pass a majority of the program verify procedures, the memory cell may be permitted to receive one or more subsequent programming pulses, thereby increasing the trapped voltage in the memory cell and thus programming the memory cell to a threshold voltage corresponding to a data value that the cell is intended to store. In this way, a reliability and/or a RWB gain of a memory device may be improved as compared to memory devices employing only a single program verify procedure, while overall programming time, circuitry overhead associated with a program verify procedure, and/or resource consumption associated with a programming procedure may be reduced as compared to programming procedures employing traditional program verify schemes.

As indicated above, FIG. 3 is provided as an example. Other examples may differ from what is described with regard to FIG. 3.

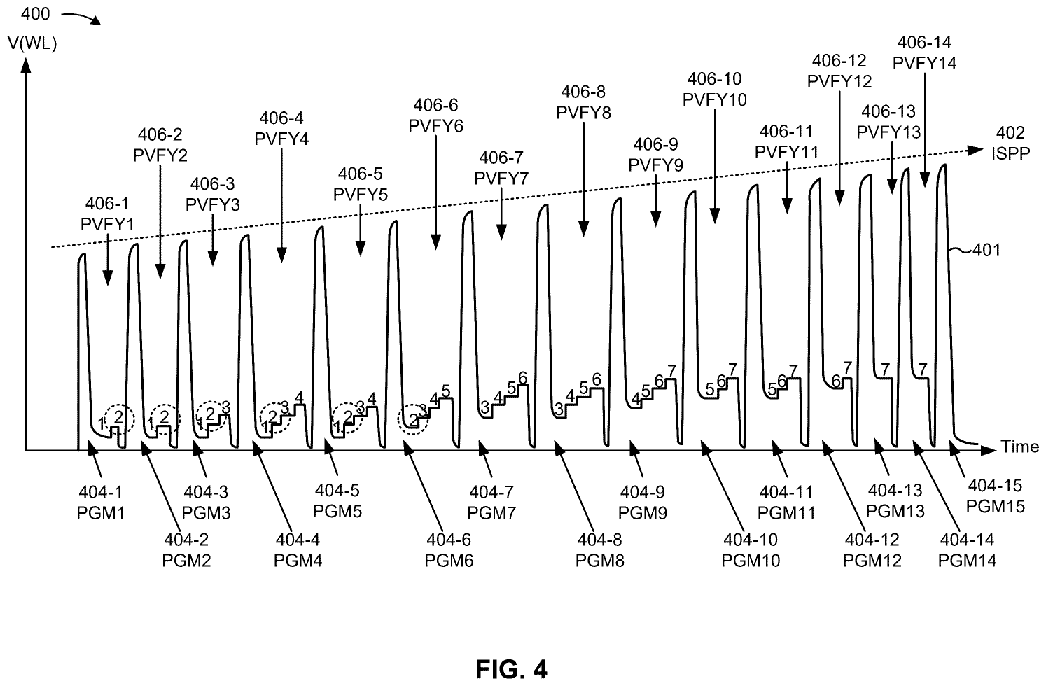

FIG. 4 is a diagram of an example 400 of a hidden majority vote program verify scheme for a memory device. The operations described in connection with FIG. 4 may be performed by the memory system 110 and/or one or more components of the memory system 110, such as the memory system controller 115, one or more memory devices 120, and/or one or more local controllers 125. Although for ease of description the programming scheme in FIG. 4 is shown and described in connection with a triple-level cell (TLC) memory (e.g., a memory in which cells are capable of indicating one of eight data values by remaining uncharged or storing one of seven threshold voltages, sometimes referred to herein as level 1 through level 7), in some other implementations the operations described in connection with FIG. 4 may be implemented in a memory that is associated with a different BPC, such as a multi-level cell (MLC) memory, a QLC memory, a penta-level cell (PLC) memory, or the like.

During a programming operation, a voltage (shown by the plot indicated by reference number 401) may be toggled between relatively high programming voltages and relatively low sensing voltages associated with program verify procedures. More particularly, as indicated by reference number 402, a memory cell (e.g., a TLC) may be programmed using an incremental step pulse programming (ISPP) programming scheme, in which a voltage of each programming pulse 404 of the programming scheme is incremented in each subsequent pulse (e.g., by an ISPP voltage). More particularly, in this ISPP programming scheme, a memory may be programmed using multiple (e.g., fifteen) programming pulses 404 (shown in FIG. 4 as “PGM”), and multiple (e.g., fourteen) program verify procedures 406 (shown in FIG. 4 as “PVFY”). During each program verify procedure 406, a number of cell levels may be verified such that each level being programmed is ultimately verified up to a certain quantity of times (e.g., six times for most cells). More particularly, the ISPP programming scheme may include fifteen programming pulses 404 (shown in FIG. 4 as a first programming pulse 404-1 (“PGM1”) through a fifteenth programming pulse 404-15 (“PGM15”)) and fourteen program verify procedures 406 (shown in FIG. 4 as a first program verify procedure 406-1 (“PVFY1”) through a fourteenth program verify procedure 406-14 (“PVFY14”)). The fourteen program verify procedures 406 may perform a total of 41 program verify operations, such as by verifying level 1 cells five times (indicated using the numeral “1” in the first program verify procedure 406-1 through the fifth program verify procedure 406-5) and verifying each of level 2 cells through level 7 cells six times (indicated using a corresponding numeral (e.g., one of “2” through “7”) in the first program verify procedure 406-1 through the fourteenth program verify procedure 406-14).

For example, following the first programming pulse 404-1, the first program verify procedure 406-1 may be performed in which a first sensing voltage (e.g., a first PV voltage) is applied (labeled with the numeral “1”) in order to verify level 1 memory cells and in which a second, higher sensing voltage is applied (labeled with the numeral “2”) in order to verify level 2 memory cells. Similarly, following the seventh programming pulse 404-7, the seventh program verify procedure 406-7 may be performed in which a first sensing voltage is applied (labeled with the numeral “3”) in order to verify level 3 memory cells, in which a second sensing voltage is applied (labeled with the numeral “4”) in order to verify level 4 memory cells, in which a third sensing voltage is applied (labeled with the numeral “5”) in order to verify level 5 memory cells, and in which a fourth sensing voltage is applied (labeled with the numeral “6”) in order to verify level 6 memory cells. The process may be repeated in a like manner for the remaining programming pulses 404 and program verify procedures 406 shown in FIG. 4.

In some implementations, after a given cell has passed a program verify procedure, the cell may be inhibited from receiving subsequent programming pulses 404, but the cell may continue to undergo additional program verify procedures, such as for a purpose of performing a majority vote program verify scheme. Following a quantity of program verify procedures (e.g., three), the memory device may determine whether the cell passes a majority (e.g., two or more) of the program verify procedures 406. If the cell passes the majority of the program verify procedures 406, the cell may be deemed to be properly programmed, and thus the cell may be inhibited from subsequent programming pulses. However, if the cell fails the majority of the program verify procedures 406, the cell may be deemed to be not properly programmed, and thus the cell may no longer be inhibited from subsequent programming pulses 404 such that the cell may be programmed to a proper threshold voltage and/or data state.

For example, in the example shown in FIG. 4, a level 2 cell may be verified six times (e.g., in the first program verify procedure 406-1 through the sixth program verify procedure 406-6), as indicated in FIG. 4 using dashed circles. In such examples, a level 2 memory cell may be permitted to receive the first programming pulse 404-1, thereby raising a voltage level trapped in the cell. During the first program verify procedure 406-1, a sensing voltage (e.g., a PV voltage) may be applied to the cell in order to detect whether the trapped voltage in the level 2 cell exceeds a threshold. If the trapped voltage exceeds a threshold (e.g., if the level 2 cell passes the first program verify procedure 406-1), a memory controller may begin a counter (e.g., using a counter circuit) associated with the level 2 cell and/or may inhibit the level 2 cell from receiving subsequent programming pulses 404 (e.g., by setting a flag in a latch or similar storage element associated with the memory). For example, the level 2 cell may be inhibited from receiving the second programming pulse 404-2 and the third programming pulse 404-3. Nonetheless, the threshold voltage of the level 2 cell may still be verified in the second program verify procedure 406-2 and the third program verify procedure 406-3.

Following the third program verify procedure 406-3, a memory controller may determine whether the level 2 cell passes a majority of the first program verify procedure 406-1, the second program verify procedure 406-2, and the third program verify procedure 406-3. If the level 2 cell passes the majority of the first program verify procedure 406-1, the second program verify procedure 406-2, and the third program verify procedure 406-3 (e.g., if a sensed voltage at the level 2 cell exceeds the PV voltage at least two of the three times), the level 2 cell may be inhibited from subsequent programming pulses (e.g., the fourth programming pulse 404-4 through the fifteenth programming pulse 404-15) so that the level 2 cell is not overprogrammed. However, if the level 2 cell does not pass the majority of the first program verify procedure 406-1, the second program verify procedure 406-2, and the third program verify procedure 406-3 (e.g., if a sensed voltage at the level 2 cell does not exceed the PV voltage at least two of the three times), the level 2 cell may be permitted to receive a subsequent programming pulse (e.g., the fourth programming pulse 404-4) in order to raise the threshold voltage of the cell.

In implementations in which the level 2 cell is permitted to receive the subsequent programming pulse (e.g., the fourth programming pulse 404-4), a bit line voltage of the level 2 cell may be adjusted (e.g., as compared to a bit line voltage associated with the first programming pulse), such as for a purpose of ensuring that the level 2 cell is not overprogrammed. More particularly, the ISPP programming scheme may include increasing voltages at each programming pulse 404, such that for a given programming pulse 404, a voltage level of the programming pulse 404 is equal to a voltage level of a prior programming pulse plus an ISPP voltage. In this way, the programming voltage for the fourth programming pulse 404-4 may be equal to the programming voltage of the second programming pulse 404-2 plus two times the ISPP voltage. Accordingly, in some implementations, a bit line voltage for the level 2 cell used during the fourth programming pulse may be set such that a difference between the programming pulse voltage and the bit line voltage is a same difference as would have been between a voltage associated with the second programming pulse 404-2 and a corresponding bit line voltage (had the level 2 cell not been prohibited from receiving the second programming pulse 404-2). More particularly, during the fourth programming pulse, the bit line voltage applied to the level 2 cell may be equal to a sum of a selective slow programming convergence (SSPC) voltage and two times an ISPP voltage (e.g., the bit line voltage for the level 2 cell may be SSPC+2xISPP). This may slow down the programming of the level 2 cell during the fourth programming pulse 404-4, ensuring that the level 2 is no over-programmed by the fourth programming pulse 404-4.

In some other implementations, if the level 2 cell does not pass the first program verify procedure 406-1, the level 2 cell may not be inhibited from receiving one or more subsequent programming pulses 404. Put another, the level 2 cell may only be first inhibited from receiving a programming pulse 404 after passing a program verify procedure 406, at which point a counter may be started (e.g., in a latch associated with the memory) in order to perform the majority vote program verify scheme, in a similar manner as described above. More particularly, if, during the first program verify procedure 406-1, the trapped voltage in the level 2 cell does not satisfy a threshold (e.g., if the level 2 cell fails the first program verify procedure 406-1), a memory controller may not inhibit the level 2 cell from receiving the next programming pulse 404. Thereafter, if the level 2 cell passes a program verify procedure, such as if a trapped voltage in the level 2 cell exceeds a threshold during the second first program verify procedure 406-2, a memory controller may begin a counter associated with the level 2 cell and/or may inhibit the level 2 cell from receiving subsequent programming pulses 404 (e.g., by setting a flag in a latch associated with the memory). For example, in a similar manner as described above, the level 2 cell may be inhibited from receiving the third programming pulse 404-3 and the fourth programming pulse 404-4. Nonetheless, the threshold voltage of the level 2 cell may still be verified in the third program verify procedure 406-3 and the fourth program verify procedure 406-4.

Following the fourth program verify procedure 406-3, a memory controller (e.g., in response to the counter indicating that the level 2 cell has been verified a quantity of times since first passing a program verify procedure, such as three total times) may determine whether the level 2 cell passes a majority of the second program verify procedure 406-2, the third program verify procedure 406-3, and the fourth program verify procedure 406-4. If the level 2 cell passes the majority of the second program verify procedure 406-2, the third program verify procedure 406-3, and the fourth program verify procedure 406-4 (e.g., if a sensed voltage at the level 2 cell exceeds the PV voltage at least two of the three times), the level 2 cell may be inhibited from subsequent programming pulses (e.g., the fifth programming pulse 404-5 through the fifteenth programming pulse 404-15). However, if the level 2 cell does not pass the majority of the second program verify procedure 406-2, the third program verify procedure 406-3, and the fourth program verify procedure 406-4 (e.g., if a sensed voltage at the level 2 cell does not exceed the PV voltage at least two of the three times), the level 2 cell may be permitted to receive a subsequent programming pulse (e.g., the fifth programming pulse 404-5). In such implementations, during the fifth programming pulse 404-5, the bit line voltage applied to the level 2 cell may be equal to a sum of an SSPC voltage and two times an ISPP voltage (e.g., the bit line voltage for the level 2 cell may be SSPC+2xISPP), in a similar manner as described above.

In some implementations, the majority vote program verify scheme described above may be implemented for only a subset of program verify procedures 406 of the programming scheme and/or a subset of programming pulses for the programming scheme. More particularly, although RTN may impact program verify procedures across all program loops and/or programming pulses, quick charge loss (QCL) and/or similar phenomena may be more dominant for faster cells (e.g., memory cells that enter earlier program verify loops for each level), and thus the effects of RTN may be more problematic for the faster cells. Accordingly, in some implementations, a memory device may verify only a subset of memory cells associated with the memory using the majority vote program verify scheme described above. For example, a memory device may only apply the majority vote program verify scheme to cells associated with a first quantity of program verify loops (e.g., the first two or three program verify loops), which may be the cells most susceptible to inaccurate readings due to RTN or similar phenomena.

As described above, although the example shown and described in connection with FIG. 4 is directed to a TLC, in some other implementations substantially similar operations may be performed in connection with a memory having a different quantity of BPC, such as a QLC, a PLC, or a similar type of memory. Moreover, because the implementations described herein are performed within a programming algorithm (e.g., because each program verify procedure 406 is performed following a respective programming pulse 404, thus “hiding” the majority vote program verify scheme within the programming algorithm), the operations described herein may be readily employed in a variety of programming schemes, such as an ISPP scheme, a programming scheme associated with a drain-to-source (D2S) program order, or a programming scheme associated with a source-to-drain (S2D) program order, among other examples. Additionally, or alternatively, the operations described above may be employed for a memory associated with a normal block usage (e.g., a full block usage) and/or that is programmed using a normal block usage program scheme, as well as programming schemes that are associated with a programming scheme that uses less than a full block, such as a half good block (HGB) program scheme, or a block by deck (BBD) program scheme, among other examples. In some implementations, the operations described above may be employed in connection with nonvolatile memory (e.g., nonvolatile memory arrays, such as memory arrays 130 or similar memory arrays), such as a NAND memory device, a RRAM device, or a PCM device, among other examples.

As indicated above, FIG. 4 is provided as an example. Other examples may differ from what is described with regard to FIG. 4.

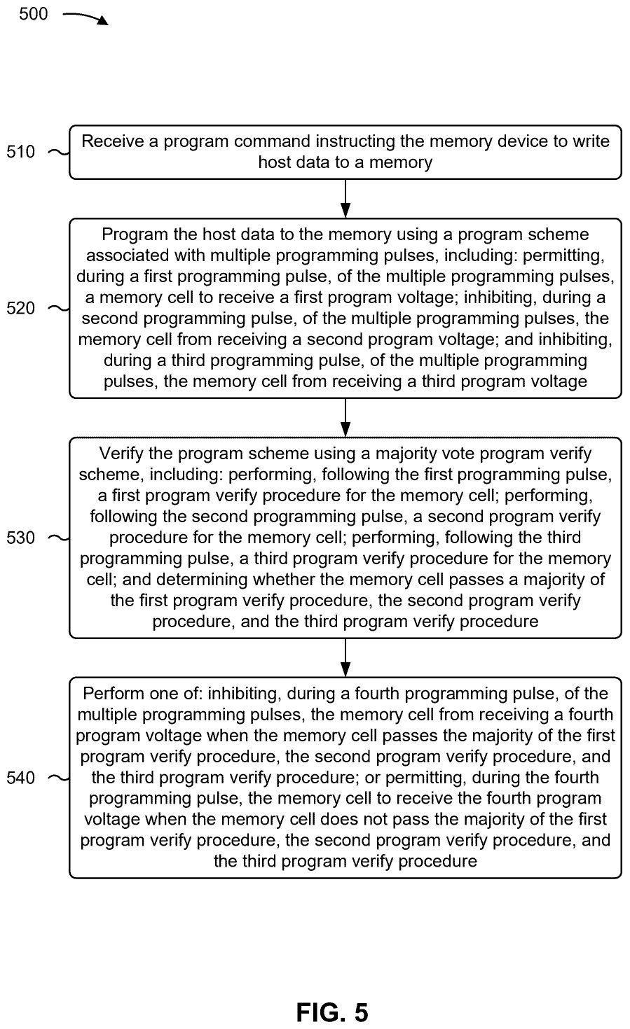

FIG. 5 is a flowchart of an example method 500 associated with a hidden majority vote program verify scheme for a memory device. In some implementations, a memory device (e.g., the memory device 120) and/or a device associated with a memory system (e.g., memory system 110) may perform or may be configured to perform the method 500. In some implementations, another device or a group of devices separate from or including the memory device (e.g., the system 100) may perform or may be configured to perform the method 500. Additionally, or alternatively, one or more components of the memory device (e.g., the memory system controller 115, the local controller 125, and/or another device associated with the memory system 110) may perform or may be configured to perform the method 500. Thus, means for performing the method 500 may include the memory device and/or one or more components of the memory device. Additionally, or alternatively, a non-transitory computer-readable medium may store one or more instructions that, when executed by the memory device (e.g., a controller of the memory device), cause the memory device to perform the method 500.

As shown in FIG. 5, the method 500 may include receiving a program command instructing the memory device to write host data to a memory (block 510). As further shown in FIG. 5, the method 500 may include programming the host data to the memory using a program scheme associated with multiple programming pulses (e.g., programming pulses 404), including: permitting, during a first programming pulse, of the multiple programming pulses, a memory cell to receive a first program voltage; inhibiting, during a second programming pulse, of the multiple programming pulses, the memory cell from receiving a second program voltage; and inhibiting, during a third programming pulse, of the multiple programming pulses, the memory cell from receiving a third program voltage (block 520). As further shown in FIG. 5, the method 500 may include verifying the program scheme using a majority vote program verify scheme, including: performing, following the first programming pulse, a first program verify procedure (e.g., one of the program verify procedures 406) for the memory cell; performing, following the second programming pulse, a second program verify procedure for the memory cell; performing, following the third programming pulse, a third program verify procedure for the memory cell; and determining whether the memory cell passes a majority of the first program verify procedure, the second program verify procedure, and the third program verify procedure (block 530). As further shown in FIG. 5, the method 500 may include performing one of: inhibiting, during a fourth programming pulse, of the multiple programming pulses, the memory cell from receiving a fourth program voltage when the memory cell passes the majority of the first program verify procedure, the second program verify procedure, and the third program verify procedure, or permitting, during the fourth programming pulse, the memory cell to receive the fourth program voltage when the memory cell does not pass the majority of the first program verify procedure, the second program verify procedure, and the third program verify procedure (block 540).

The method 500 may include additional aspects, such as any single aspect or any combination of aspects described below and/or described in connection with one or more other methods or operations described elsewhere herein.

In a first aspect, the method 500 includes determining, by the memory device, that the memory cell passes the first program verify procedure, and inhibiting, by the memory device, the memory cell from receiving the second program voltage based on determining that the memory cell passes the first program verify procedure.

In a second aspect, alone or in combination with the first aspect, verifying the program scheme using the majority vote program verify scheme comprises verifying only a subset of memory cells associated with the memory using the majority vote program verify scheme, and wherein the memory cell is included in the subset of memory cells.

In a third aspect, alone or in combination with one or more of the first and second aspects, the method 500 includes permitting, by the memory device and during the fourth programming pulse, the memory cell to receive the fourth program voltage, and applying, by the memory device and during the fourth programming pulse, a bit line voltage to the memory cell, wherein the bit line voltage corresponds to a sum of a selective slow programming convergence voltage and two times an incremental step pulse programming voltage.

In a fourth aspect, alone or in combination with one or more of the first through third aspects, the program scheme is associated with at least one of an incremental step pulse programming scheme, a drain-to-source program order, a source-to-drain program order, a normal block usage program scheme, a half good block program scheme, or a block by deck program scheme.

In a fifth aspect, alone or in combination with one or more of the first through fourth aspects, the memory cell is associated with one of a triple level cell or a quad level cell.

In a sixth aspect, alone or in combination with one or more of the first through fifth aspects, the memory device is associated with one of a NAND memory device, a resistive random-access memory device, or a phase-change memory device.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

In some implementations, a memory device includes one or more components configured to: receive, from a host device, a program command instructing the memory device to write host data to a memory; and program the host data to the memory using a program scheme associated with multiple programming pulses, including: permitting, during a first programming pulse, of the multiple programming pulses, a memory cell to receive a first program voltage; inhibiting, during a second programming pulse, of the multiple programming pulses, the memory cell from receiving a second program voltage; and inhibiting, during a third programming pulse, of the multiple programming pulses, the memory cell from receiving a third program voltage; verify the program scheme using a majority vote program verify scheme, including: performing, following the first programming pulse, a first program verify procedure for the memory cell; performing, following the second programming pulse, a second program verify procedure for the memory cell; performing, following the third programming pulse, a third program verify procedure for the memory cell; and determining whether the memory cell passes a majority of the first program verify procedure, the second program verify procedure, and the third program verify procedure; and perform one of: inhibiting, during a fourth programming pulse, of the multiple programming pulses, the memory cell from receiving a fourth program voltage when the memory cell passes the majority of the first program verify procedure, the second program verify procedure, and the third program verify procedure, or permitting, during the fourth programming pulse, the memory cell to receive the fourth program voltage when the memory cell does not pass the majority of the first program verify procedure, the second program verify procedure, and the third program verify procedure.

In some implementations, a method includes receiving, by a memory device from a host device, a program command instructing the memory device to write host data to a memory; programming, by the memory device, the host data to the memory using a program scheme associated with multiple programming pulses, including: permitting, during a first programming pulse, of the multiple programming pulses, a memory cell to receive a first program voltage; inhibiting, during a second programming pulse, of the multiple programming pulses, the memory cell from receiving a second program voltage; and inhibiting, during a third programming pulse, of the multiple programming pulses, the memory cell from receiving a third program voltage; verifying, by the memory device, the program scheme using a majority vote program verify scheme, including: performing, following the first programming pulse, a first program verify procedure for the memory cell; performing, following the second programming pulse, a second program verify procedure for the memory cell; performing, following the third programming pulse, a third program verify procedure for the memory cell; and determining whether the memory cell passes a majority of the first program verify procedure, the second program verify procedure, and the third program verify procedure; and performing, by the memory device, one of: inhibiting, during a fourth programming pulse, of the multiple programming pulses, the memory cell from receiving a fourth program voltage when the memory cell passes the majority of the first program verify procedure, the second program verify procedure, and the third program verify procedure, or permitting, during the fourth programming pulse, the memory cell to receive the fourth program voltage when the memory cell does not pass the majority of the first program verify procedure, the second program verify procedure, and the third program verify procedure.

In some implementations, a non-transitory computer-readable medium storing a set of instructions includes one or more instructions that, when executed by one or more processors of a memory device, cause the memory device to: receive, from a host device, a program command instructing the memory device to write host data to a memory; and program the host data to the memory using a program scheme associated with multiple programming pulses, including: permitting, during a first programming pulse, of the multiple programming pulses, a memory cell to receive a first program voltage; inhibiting, during a second programming pulse, of the multiple programming pulses, the memory cell from receiving a second program voltage; and inhibiting, during a third programming pulse, of the multiple programming pulses, the memory cell from receiving a third program voltage; verify the program scheme using a majority vote program verify scheme, including: performing, following the first programming pulse, a first program verify procedure for the memory cell; performing, following the second programming pulse, a second program verify procedure for the memory cell; performing, following the third programming pulse, a third program verify procedure for the memory cell; and determining whether the memory cell passes a majority of the first program verify procedure, the second program verify procedure, and the third program verify procedure; and perform one of: inhibiting, during a fourth programming pulse, of the multiple programming pulses, the memory cell from receiving a fourth program voltage when the memory cell passes the majority of the first program verify procedure, the second program verify procedure, and the third program verify procedure, or permitting, during the fourth programming pulse, the memory cell to receive the fourth program voltage when the memory cell does not pass the majority of the first program verify procedure, the second program verify procedure, and the third program verify procedure.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
receive, from a host device, a program command instructing the memory device to write host data to a memory; and
program the host data to the memory using a program scheme associated with multiple programming pulses, including:
permitting, during a first programming pulse, of the multiple programming pulses, a memory cell to receive a first program voltage;
inhibiting, during a second programming pulse, of the multiple programming pulses, the memory cell from receiving a second program voltage; and
inhibiting, during a third programming pulse, of the multiple programming pulses, the memory cell from receiving a third program voltage;
verify the program scheme using a majority vote program verify scheme, including:
performing, following the first programming pulse, a first program verify procedure for the memory cell;
performing, following the second programming pulse, a second program verify procedure for the memory cell;
performing, following the third programming pulse, a third program verify procedure for the memory cell; and
determining whether the memory cell passes a majority of the first program verify procedure, the second program verify procedure, and the third program verify procedure; and
perform one of:
inhibiting, during a fourth programming pulse, of the multiple programming pulses, the memory cell from receiving a fourth program voltage when the memory cell passes the majority of the first program verify procedure, the second program verify procedure, and the third program verify procedure, or
permitting, during the fourth programming pulse, the memory cell to receive the fourth program voltage when the memory cell does not pass the majority of the first program verify procedure, the second program verify procedure, and the third program verify procedure.

2. The memory device of claim 1, wherein the one or more components are further configured to:
determine that the memory cell passes the first program verify procedure; and
inhibit the memory cell from receiving the second program voltage based on determining that the memory cell passes the first program verify procedure.

3. The memory device of claim 1, wherein the one or more components, to verify the program scheme using the majority vote program verify scheme, are configured to verify only a subset of memory cells associated with the memory using the majority vote program verify scheme, and
wherein the memory cell is included in the subset of memory cells.

4. The memory device of claim 1, wherein the one or more components are further configured to:
permit, during the fourth programming pulse, the memory cell to receive the fourth program voltage; and
apply, during the fourth programming pulse, a bit line voltage to the memory cell, wherein the bit line voltage corresponds to a sum of a selective slow programming convergence voltage and two times an incremental step pulse programming voltage.

5. The memory device of claim 1, wherein the program scheme is associated with at least one of:
an incremental step pulse programming scheme,
a drain-to-source program order,
a source-to-drain program order,
a normal block usage program scheme,
a half good block program scheme, or
a block by deck program scheme.

6. The memory device of claim 1, wherein the memory cell is associated with one of a triple level cell or a quad level cell.

7. The memory device of claim 1, wherein the memory device is associated with one of a NAND memory device, a resistive random-access memory device, or a phase-change memory device.

8. A method, comprising:
receiving, by a memory device from a host device, a program command instructing the memory device to write host data to a memory;
programming, by the memory device, the host data to the memory using a program scheme associated with multiple programming pulses, including:
permitting, during a first programming pulse, of the multiple programming pulses, a memory cell to receive a first program voltage;
inhibiting, during a second programming pulse, of the multiple programming pulses, the memory cell from receiving a second program voltage; and
inhibiting, during a third programming pulse, of the multiple programming pulses, the memory cell from receiving a third program voltage;
verifying, by the memory device, the program scheme using a majority vote program verify scheme, including:
performing, following the first programming pulse, a first program verify procedure for the memory cell;
performing, following the second programming pulse, a second program verify procedure for the memory cell;
performing, following the third programming pulse, a third program verify procedure for the memory cell; and
determining whether the memory cell passes a majority of the first program verify procedure, the second program verify procedure, and the third program verify procedure; and
performing, by the memory device, one of:
inhibiting, during a fourth programming pulse, of the multiple programming pulses, the memory cell from receiving a fourth program voltage when the memory cell passes the majority of the first program verify procedure, the second program verify procedure, and the third program verify procedure, or
permitting, during the fourth programming pulse, the memory cell to receive the fourth program voltage when the memory cell does not pass the majority of the first program verify procedure, the second program verify procedure, and the third program verify procedure.

9. The method of claim 8, further comprising:
determining, by the memory device, that the memory cell passes the first program verify procedure; and
inhibiting, by the memory device, the memory cell from receiving the second program voltage based on determining that the memory cell passes the first program verify procedure.

10. The method of claim 8, wherein verifying the program scheme using the majority vote program verify scheme comprises verifying only a subset of memory cells associated with the memory using the majority vote program verify scheme, and
wherein the memory cell is included in the subset of memory cells.

11. The method of claim 8, further comprising:
permitting, by the memory device and during the fourth programming pulse, the memory cell to receive the fourth program voltage; and
applying, by the memory device and during the fourth programming pulse, a bit line voltage to the memory cell, wherein the bit line voltage corresponds to a sum of a selective slow programming convergence voltage and two times an incremental step pulse programming voltage.

12. The method of claim 8, wherein the program scheme is associated with at least one of:
an incremental step pulse programming scheme,
a drain-to-source program order,
a source-to-drain program order,
a normal block usage program scheme,
a half good block program scheme, or
a block by deck program scheme.

13. The method of claim 8, wherein the memory cell is associated with one of a triple level cell or a quad level cell.

14. The method of claim 8, wherein the memory device is associated with one of a NAND memory device, a resistive random-access memory device, or a phase-change memory device.

15. A non-transitory computer-readable medium storing a set of instructions, the set of instructions comprising:
one or more instructions that, when executed by one or more processors of a memory device, cause the memory device to:
receive, from a host device, a program command instructing the memory device to write host data to a memory; and
program the host data to the memory using a program scheme associated with multiple programming pulses, including:
permitting, during a first programming pulse, of the multiple programming pulses, a memory cell to receive a first program voltage;
inhibiting, during a second programming pulse, of the multiple programming pulses, the memory cell from receiving a second program voltage; and
inhibiting, during a third programming pulse, of the multiple programming pulses, the memory cell from receiving a third program voltage;
verify the program scheme using a majority vote program verify scheme, including:
performing, following the first programming pulse, a first program verify procedure for the memory cell;
performing, following the second programming pulse, a second program verify procedure for the memory cell;
performing, following the third programming pulse, a third program verify procedure for the memory cell; and
determining whether the memory cell passes a majority of the first program verify procedure, the second program verify procedure, and the third program verify procedure; and
perform one of:
inhibiting, during a fourth programming pulse, of the multiple programming pulses, the memory cell from receiving a fourth program voltage when the memory cell passes the majority of the first program verify procedure, the second program verify procedure, and the third program verify procedure, or
permitting, during the fourth programming pulse, the memory cell to receive the fourth program voltage when the memory cell does not pass the majority of the first program verify procedure, the second program verify procedure, and the third program verify procedure.

16. The non-transitory computer-readable medium of claim 15, wherein the one or more instructions further cause the memory device to:
determine that the memory cell passes the first program verify procedure; and
inhibit the memory cell from receiving the second program voltage based on determining that the memory cell passes the first program verify procedure.

17. The non-transitory computer-readable medium of claim 15, wherein the one or more instructions, that cause the memory device to verify the program scheme using the majority vote program verify scheme, cause the memory device to verify only a subset of memory cells associated with the memory using the majority vote program verify scheme, and
wherein the memory cell is included in the subset of memory cells.

18. The non-transitory computer-readable medium of claim 15, wherein the one or more instructions further cause the memory device to:
permit, during the fourth programming pulse, the memory cell to receive the fourth program voltage; and
apply, during the fourth programming pulse, a bit line voltage to the memory cell, wherein the bit line voltage corresponds to a sum of a selective slow programming convergence voltage and two times an incremental step pulse programming voltage.

19. The non-transitory computer-readable medium of claim 15, wherein the program scheme is associated with at least one of:
an incremental step pulse programming scheme,
a drain-to-source program order,
a source-to-drain program order,
a normal block usage program scheme,
a half good block program scheme, or
a block by deck program scheme.

20. The non-transitory computer-readable medium of claim 15, wherein the memory cell is associated with one of a triple level cell or a quad level cell.
